(19) United States
(12) Patent Application Publication
(10) Pub. No.: US 2008/0211011 A1
(43) Pub. Date: Sep. 4, 2008

(54) NONVOLATILE SEMICONDUCTOR MEMORY ELEMENT AND NONVOLATILE SEMICONDUCTOR MEMORY DEVICE

(76) Inventors: Akira TAKASHIMA, Tokyo (JP); Kouichi Muraoka, Sagamihara-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/024,297

(22) Filed: Feb. 1, 2008

(30) Foreign Application Priority Data
Feb. 20, 2007 (JP) 2007-39633

(51) Int. Cl. H01L 29/792

(52) U.S. Cl. 257/324; 257/E29.309

(57) ABSTRACT

It is made possible to provide a nonvolatile semiconductor memory element that can be miniaturized and can store multi-level data. A nonvolatile semiconductor memory element includes a semiconductor substrate; a source region and a drain region formed at a distance from each other in the semiconductor substrate; and a gate structure formed on a portion of the semiconductor substrate, the portion being located between the source region and the drain region. The gate structure includes a tunnel insulating layer, a resistance variable layer formed above the tunnel insulating layer and made of a metal oxide, and a first electrode formed on the resistance variable layer.

### CROSS-REFERENCE TO RELATED APPLICATION

This application is based upon and claims the benefit of priority from prior Japanese Patent Application No. 2007-39633 filed on Feb. 20, 2007 in Japan, the entire contents of which are incorporated herein by reference.

### BACKGROUND OF THE INVENTION

1. Field of the Invention

The present invention relates to a nonvolatile semiconductor memory element that has a resistance variable layer formed with a metal oxide in a gate structure, and a nonvolatile semiconductor memory device.

2. Related Art

Flash memories that are used for recording media such as digital cameras and portable audio devices have higher capacities and are rapidly becoming less expensive in recent years. It would not be an overstatement to say that the high-capacity, inexpensive flash memories have been realized by a dramatic increase in data recording density per chip through the miniaturization and multi-level memory techniques. However, if a flash memory cell becomes as small as several tens of nanometers in line width, the amount of charges that can be stored in the charge storage layer becomes so small that storing multi-level data becomes difficult. Therefore, there is an increasing demand for novel nonvolatile memories that can be miniaturized and can still store multi-level data.

Such nonvolatile memories include resistance variable memories such as ReRAM (Resistance RAM) and PCRAM (Phase Change RAM) (see W. W. Zhuang, et al., IEDM Tech. Dig. (2002), for example). Each memory cell of a resistance variable memory is fundamentally a simple two-terminal resistance variable element that has a resistance variable material interposed between electrodes. Such a resistance variable element is characterized in setting the resistance value at a desired value in an analog fashion, and it is considered that this variable resistance value can be used for storing multi-level data.

However, resistance changes in a PCRAM are phase transitions caused by resistance heating in a crystalline structure. Accordingly, as the PCRAM becomes smaller, disturbance is easily caused due to thermal interference between adjacent cells, and it is expected that the reliability is degraded.

In a ReRAM, on the other hand, a resistance change can be caused in a very small region of several nanometers in size (see K. Szot, et al., Nature Materials, 51,312 (2006), for example). Also, a ReRAM has thermal stability. Thus, ReRAMs are considered to be memories with high reliability in spite of miniaturization.

To put ReRAMs as novel flash memories to practical use, the ReRAMs need to have circuit structures suitable for miniaturization, and the manufacture of the ReRAMs needs to be easy. There have been two types of circuit structures (memory arrays): cross-point memory arrays, and NOR memory arrays each having “1T-1R” memory cells each having one transistor and one resistance variable element.

Each cell of a cross-point memory array is characterized by being 4F² in size, with F being the line width (see I. G. Baek, et al., IEDM Tech. Dig. (2005), for example). However, each cell requires a diode for preventing disturbance into the cells in the neighborhood. As a result, the manufacturing process becomes complicated.

Meanwhile, the minimum size of each memory cell of a NOR memory array having “1T-1R” memory cells is 6F². Therefore, even after miniaturization, it is difficult to achieve high density (see JP-A 2006-135335 (KOKAI), for example).

### SUMMARY OF THE INVENTION

The present invention has been made in view of these circumstances, and an object thereof is to provide a nonvolatile semiconductor memory element and a nonvolatile semiconductor memory device that can be miniaturized and can store multi-level data.

A nonvolatile semiconductor memory element according to a first aspect of the present invention includes: a semiconductor substrate; a source region and a drain region formed at a distance from each other in the semiconductor substrate; and a gate structure formed on a portion of the semiconductor substrate, the portion being located between the source region and the drain region, the gate structure including a tunnel insulating layer, a resistance variable layer formed above the tunnel insulating layer and made of a metal oxide, and a first electrode formed on the resistance variable layer.

A nonvolatile semiconductor memory device according to a second aspect of the present invention includes: a plurality of nonvolatile semiconductor memory elements according to the first aspect, the nonvolatile semiconductor memory elements being arranged in a matrix form, the first electrodes of the nonvolatile semiconductor memory elements in each column being connected to a word line, the nonvolatile semiconductor memory elements in each row being aligned in series.

A nonvolatile semiconductor memory device according to a third aspect of the present invention includes: a plurality of nonvolatile semiconductor memory elements according to the first aspect, the nonvolatile semiconductor memory elements being arranged in a matrix form, the first electrodes of the nonvolatile semiconductor memory elements in each column being connected to a common word line, the drain regions of the nonvolatile semiconductor memory elements in each row being connected to a common bit line, and the source regions of the nonvolatile semiconductor memory elements in each row being connected to ground.

### BRIEF DESCRIPTION OF THE DRAWINGS

FIG. 1 is a cross-sectional view of a memory element of a nonvolatile semiconductor memory device in accordance with a first embodiment;

FIG. 2 shows the characteristics of a nonpolar-type resistance variable layer;

FIG. 3 shows the characteristics of a bipolar-type resistance variable layer;

FIG. 4 is an equivalent circuit of a memory element of the first or second embodiment in a low resistance state;

FIG. 5 is an equivalent circuit of a memory element of the first or second embodiment in a high resistance state;

FIG. 6 shows a NAND memory array formed with memory elements of Example 1;

FIG. 7 is a cross-sectional view of a memory element of a nonvolatile semiconductor memory device in accordance with the second embodiment; and

FIG. 8 shows a NOR memory array formed with memory elements of Example 1.

### DESCRIPTION OF THE PREFERRED EMBODIMENTS

The following is a description of embodiments of the present invention, with reference to the accompanying drawings.

### First Embodiment

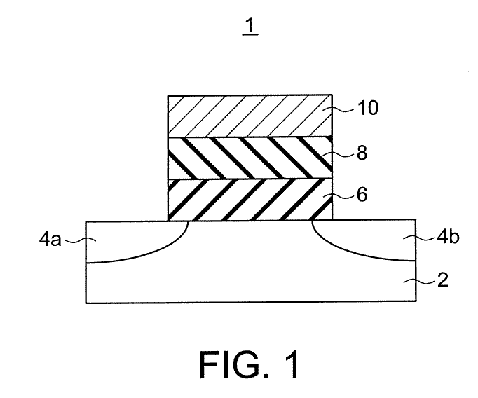

A nonvolatile semiconductor memory device in accordance with a first embodiment of the present invention is described. The nonvolatile semiconductor memory device of this embodiment has a plurality of memory cells (or memory elements). As shown in FIG. 1, each of the memory cells 1 includes: a source region 4a and a drain region 4b that are formed at a distance from each other in a semiconductor substrate (a silicon substrate, for example) 2; a tunnel insulating layer 6 that is formed at a position located on the semiconductor substrate 2 and between the source region 4a and the drain region 4b; a resistance variable layer 8 that is formed on the tunnel insulating layer 6; and an electrode 10 that is formed on the resistance variable layer 8. In short, each memory cell 1 in accordance with this embodiment is a transistor having the source region 4a, the drain region 4b, and a gate structure in which the tunnel insulating layer 6, the resistance variable layer 8, and the electrode 10 are stacked on a portion of the semiconductor substrate located between the source region 4a and the drain region 4b.

The tunnel insulating layer 6 may be formed with silicon oxide, silicon oxynitride, alumina, or a high-dielectric material that is known as “high-k”, such as an oxide containing at least one of Zr, Hf, La, and the likes.

A metal oxide is used for the resistance variable layer 8. A metal or semiconductor is used for the electrode 10.

Next, operations to be performed by the nonvolatile semiconductor memory device of this embodiment are described.

First, the four operations of forming, writing, erasing, and reading are described.

“Forming” is to apply a constant voltage that is slightly high to the resistance variable layer formed with a metal oxide from the electrode. This is the first operation to be carried out to enable the memory cell to function as a resistance variable memory. The constant voltage is equal to or higher than a later described write voltage, and is a current or voltage that does not reach a breakdown beyond restoration. Therefore, it is preferable that compliance is used to prevent excess current and voltage in the memory cell.

Writing is performed by applying a constant voltage to the memory cell, so that the resistance value of the memory cell is changed from a high resistance state (hereinafter also referred to as HRS) to a low resistance state (hereinafter also referred to as LRS).

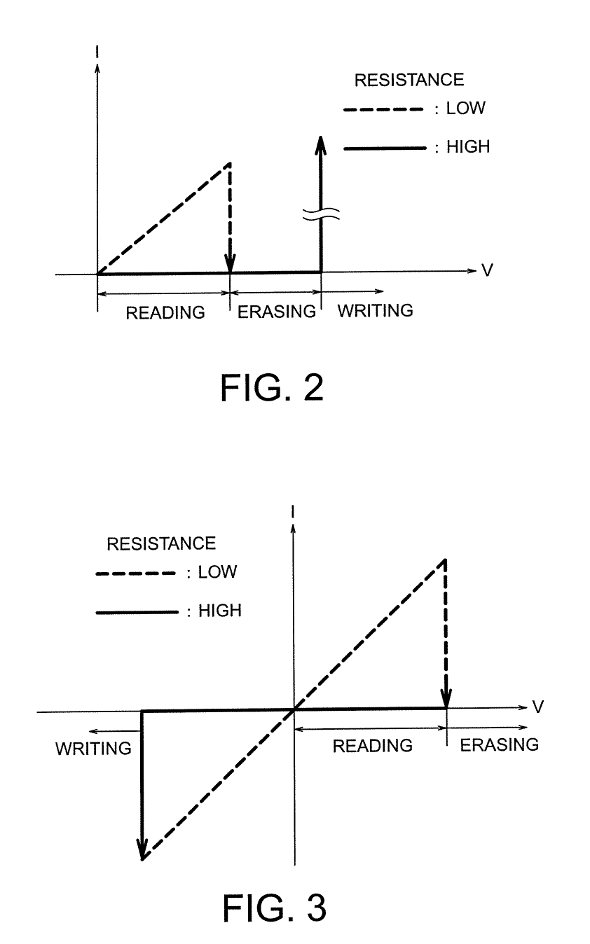

Erasing is the opposite of writing, and is performed to change the resistance value from LRS to HRS. The erasing operation varies depending on whether the resistance variable memory is of a nonpolar type or of a bipolar type. As shown in FIG. 2, in a nonpolar-type erasing operation, a constant voltage lower than the constant voltage to be applied in a writing operation is applied. As shown in FIG. 3, in a bipolar-type erasing operation, a constant voltage of the opposite polarity to the constant voltage to be applied in a writing operation is applied. By changing the voltage at the time of erasing to a pulse voltage, the resistance value between LRS and HRS can be varied in an analog fashion, and can take multiple values (see W. W. Zhuang, et al., IEDM Tech. Dig. (2002), for example). The resistance value can be controlled by adjusting the width, size, and the number of pulse voltages. Whether the resistance variable memory is of a nonpolar type or of a bipolar type is determined by the material of the resistance variable layer 8.

Examples of nonpolar-type materials include oxygen-deficient metal oxides such as ZrOₓ (1<x<2), TiOₓ (1<x<2), HfOₓ (1<x<2), V₂O_{y} (2<y<5), Nb₂O_{y} (2<y<5), Ta₂O_{y} (2<y<5), and NiO_{z} (0.5<z<1). By performing “forming”, a local conductive path is formed in a direction substantially perpendicular to the film plane of the layer made of a nonpolar-type material. A resistance change is normally caused through an oxidation-reduction reaction in the vicinity of the anode side of the resistance variable layer.

Examples of bipolar-type materials include CuO_{z} (0.5<z<1), ZnO_{z} (0.5<z<1), oxides containing lanthanoid, an alkaline earth metal, and manganese (such as PrₓCa₁₋ₓMnO₃ (0<x<1) and LaₓSr₁₋ₓMnO₃ (0<x<1)), oxides containing Ti and an alkaline earth metal (such as SrTiO₃), oxides containing Zr and an alkaline earth metal (such as SrZrO₃), oxides containing Hf and an alkaline earth metal (such as HfBaO₃, HfCaO₃, and HfSrO₃), PbZrₓTi₁₋ₓO, LaCoO₃, LaCaO₃, SeFeO₃, RuSrGdCuO, and YBaCuO. Further, 3.0 atomic % or less of any of Al, V, Nb, Ta, Cr, Mo, and W may be added to those metal oxides to be used as the bipolar-type materials. If the additive amount of any of those elements is larger than 3.0 atomic %, the resultant material becomes a conductive material, which is not preferred.

Reading is performed by measuring the resistance value based on the amount of the current flowing through the memory cell when a voltage lower than the voltage to be used for erasing is applied, regardless of the polarity of the voltage.

It should be noted here that voltages to be used for forming, writing and erasing depend on the materials, the oxygen deficiency, the amount of dopant such as Cr or V, and the crystalline state of the metal oxide forming the resistance variable layer 8.

Next, operations to be performed by each memory cell of this embodiment are described. Each memory cell of this embodiment first performs the forming of the resistance variable layer 8. With the fact that voltage dividing is caused in the tunnel insulating layer 6 of the gate structure being taken into consideration, this forming is performed to prevent a breakdown of the tunnel insulating layer 6. A voltage necessary for the metal oxide layer to become the resistance variable layer 8 having an electric resistance variable with applied voltages is applied between the electrode 10 and semiconductor substrate 2. At the time of forming, the resistance variable layer 8 is put into LRS, and a current easily flows. However, the tunnel insulating layer 6 serves to restrain the current flowing at the time of forming, or serves as “compliance”.

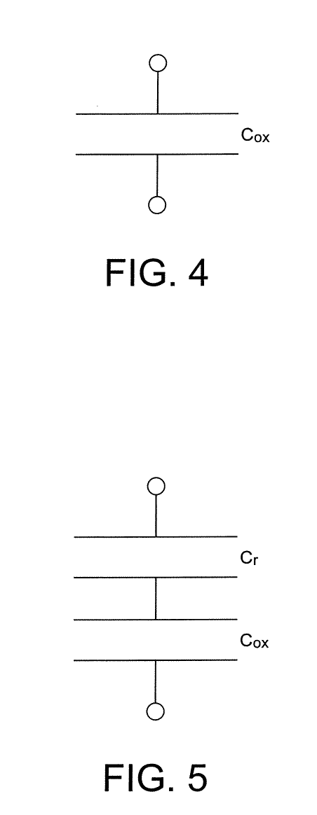

Writing is performed by applying a write voltage between the electrode 10 of the gate structure and the semiconductor substrate 2, so that the resistance variable layer 8 is changed from HRS to LRS. As the resistance value of the resistance variable layer 8 becomes sufficiently small at this point, the equivalent circuit of the gate structure becomes as shown in FIG. 4. In other words, the capacitance C_{low} of the gate structure becomes substantially equal to the capacitance Cₒₓ of the tunnel insulating layer 6.

Erasing is performed by applying a constant voltage lower than the write voltage so that the resistance variable layer 8 is changed from LRS to HRS. Since the resistance variable layer 8 has high resistance in HRS, a voltage drop is caused in the resistance variable layer 8, and the equivalent circuit of the gate structure becomes as shown in FIG. 5. In other words, the capacitance C_{high} of the entire gate in HRS becomes equal to the series capacitance of the resistance variable layer 8 and the tunnel insulating layer 6:

$${C}_{high} = {C}_{ox} {\{ 1 + \frac{{ɛ}_{ox} {d}_{R}}{{ɛ}_{R} {d}_{ox}} \}}^{- 1}$$

where Cₒₓ represents the capacitance of the tunnel insulating layer 6, εₒₓ represents the relative permittivity of the tunnel insulating layer 6, dₒₓ represents the layer thickness of the tunnel insulating layer 6, ε_{R} represents the relative permittivity of the resistance variable layer 8, and d_{R} represents the layer thickness of the resistance variable layer 8.

The fact that the resistance and capacitance of the resistance variable layer 8 vary at the same time has been confirmed by S. Tsui and others (see S. Q. Tsui, et al., Appl. Phys. Lett. 85, 317 (2004), for example).

Also, a pulse voltage is used for erasing, so that the resistance value and capacitance can be varied in an analog fashion and can take multiple values (see W. W. Zhuang, et al., IEDM Tech. Dig. (2002), for example).

In a reading operation, a shift of the threshold value of the memory cell or the transistor is read. When a read voltage is applied, the amount of charge induced in the gate of the transistor varies or the threshold value of the transistor at the time of reading varies, due to the difference in the resistance value and the capacitance of the gate structure. This shift of the threshold value is read in the same manner as in a flash memory. In each memory cell 1 of this embodiment, it is considered that the resistance shifts at the interface between the resistance variable layer 8 and the electrode 10.

As described above, in accordance with the first embodiment, each memory cell 1 has the resistance variable layer 8 in the gate structure of the transistor, and the minimum size of the memory cell 1 is 4F2 as in each memory cell of a cross-point memory array. Accordingly, miniaturization is realized. Also, the resistance value can be changed between LRS and HRS in an analog fashion by applying a pulse voltage at the time of erasing. Accordingly, the threshold voltage of the transistor can be varied in an analog fashion. Thus, the multi-level technique for flash memories can be utilized.

### Second Embodiment

Next, a nonvolatile semiconductor memory device in accordance with a second embodiment of the present invention is described. The nonvolatile semiconductor memory device of this embodiment has the same structure as the memory device of the first embodiment, except that each memory cell (memory element) 1 shown in FIG. 1 is replaced with a memory cell (memory element) 1A shown in FIG. 7. As shown in FIG. 7, the memory cell 1A includes: a source region 4a and a drain region 4b that are formed at a distance from each other in a semiconductor substrate (a silicon substrate, for example) 2; a tunnel insulating layer 6 that is formed on the portion of the semiconductor substrate 2 located between the source region 4a and the drain region 4b; a lower electrode 7 that is formed on the tunnel insulating layer 6; a resistance variable layer 8 that is formed on the lower electrode 7; and an upper electrode 10 that is formed on the resistance variable layer 8. This memory cell 1A of this embodiment is a transistor that has the source region 4a, the drain region 4b, and a gate structure in which the tunnel insulating layer 6, the lower electrode 7, the resistance variable layer 8, and the upper electrode 10 are stacked on the portion of the semiconductor substrate 2 located between the source region 4a and the drain region 4b.

As in the first embodiment, “forming” of the resistance variable layer 8 of the memory cell 1A is first performed in the memory device of this embodiment. Writing, reading, and erasing are also performed in the same manner as in the first embodiment. In the memory cell 1A in accordance with this embodiment, it is considered that the resistance varies at the interface between the lower electrode 7 and the resistance variable layer 8, and at the interface between the resistance variable layer 8 and the upper electrode 10. To prevent diffusion of the metal contained in the resistance variable layer 8 into the insulating layer 6, it is preferable that the lower electrode 7 is made of a material that can serve as a barrier. With such a material, the lower electrode 7 can prevent mutual diffusion of the elements of the tunnel insulating layer 6 and the resistance variable layer 8 even in a high-temperature process.

As described above, in accordance with the second embodiment, the memory cell 1A has the resistance variable layer 8 in the gate structure of the transistor, and the minimum size of the memory cell is 4F2 as in each memory cell of a cross-point memory array. Accordingly, miniaturization can be realized. Also, the resistance value can be changed between LRS and HRS in an analog fashion by applying a pulse voltage at the time of erasing. Accordingly, the threshold voltage of the transistor can be varied in an analog fashion, and can take multiple values.

Next, the differences between the memory cells of the first and second embodiments and similar memory cells are described.

The memory cells similar to the memory cells of the above embodiments include MNOS (Metal-Nitride-Oxide-Si) structures, MONOS (Metal-Oxide-Nitride-Oxide-Si) structures, and flash memories. In each of the MNOS structures and the MONOS structures, charges are stored at the interface between a nitride layer made of SiN and an oxide layer made of SiO₂ or in a nitride layer made of SiN, and the threshold value of the transistor is shifted by the charges. There are also cases where a metal oxide layer, instead of SiN, is used as the charge storage layer (see JP-A 2004-336044 (KOKAI), for example).

In the first and second embodiments, however, forming is performed to change a metal oxide layer to the resistance variable layer 8 that has electric resistance varied with applied voltages. This resistance variable layer 8 differs from the charge storage layer of a flash memory.

In a flash memory, a metal oxide may be used as an insulating film between the control gate and the floating gate, so as to hold the charges stored in the floating gate.

In the first and second embodiments, on the other hand, the resistance variable layer 8 made of a metal oxide has a variable threshold value, which is a different aspect from a flash memory. A memory device of the first or second embodiments can perform writing in a memory cell in 10 nsec. On the other hand, a flash memory requires several μsec or longer for writing. Accordingly, a memory device of the first or second embodiments can perform writing at a higher speed than a flash memory.

### EXAMPLES

Next, examples of the present invention are described.

### Example 1

A memory cell in Example 1 is a memory cell 1 having the gate structure of the first embodiment shown in FIG. 1. The memory cell 1 has a nonpolar-type material used as the resistance variable layer 8. The memory cell 1 of this example includes: an n-type source region 4a and drain region 4b that are formed in a silicon substrate 2; a tunnel insulating layer 6 that has a layer thickness of 4 nm and is made of SiO₂; a resistance variable layer 8 that has a layer thickness of 20 nm and is made of HfOₓ (x=1.0 to 2.0); and an electrode 10 that has a film thickness of 20 nm and is made of Pt. The relative permittivity of SiO₂ is 3.9, and the relative permittivity of HfOₓ is 20. The capacitance C_{high} in HRS is equal to the series capacitance of the tunnel insulating layer 6 made of SiO₂ and the resistance variable layer 8 made of HfOₓ, and therefore, is expressed as:

$$\begin{matrix}{C}_{high} = {C}_{ox} {\{ 1 + \frac{{ɛ}_{ox} {d}_{R}}{{ɛ}_{R} {d}_{ox}} \}}^{- 1} \\ = {C}_{ox} {\{ 1 + \frac{3.9 \times 20}{20 \times 4} \}}^{- 1} \\ = \frac{{C}_{ox}}{2}\end{matrix}$$

where Cₒₓ represents the capacitance of the tunnel insulating layer 6 made of SiO₂, εₒₓ represents the relative permittivity of the tunnel insulating layer 6 made of SiO₂, dₒₓ represents the layer thickness of the tunnel insulating layer 6 made of SiO_{2,} ε_{R} represents the relative permittivity of the resistance variable layer 8 made of HfOₓ, and d_{R} represents the layer thickness of the resistance variable layer 8 made of HfOₓ.

Meanwhile, it became apparent that the capacitance C_{low} in LRS is almost equal to Cₒₓ, as the resistance of the resistance variable layer 8 is sufficiently low.

As can be seen from the above equation, where a read voltage V is applied, the capacitance in LRS is almost twice the capacitance in HRS. Accordingly, it is found that, to store the same amount of charges in the memory cell of this example in both cases of LRS and HRS, a voltage twice as high as the voltage applied in LRS is required in HRS, and the threshold value of the transistor shifts.

The resistance value of the resistance variable layer 8 is then arbitrarily set at a value between the value of LRS and the value of HRS, so as to change the threshold value. Here, the multi-level data recording method is described. The resistance value of the resistance variable layer 8 can be varied between the value of LRS and the value of HRS in an analog fashion by applying a pulse voltage at the time of erasing. For example, when the resistance variable layer 8 was in LRS, a pulse voltage of 5.0 V in height and 500 ns in width was applied, and the resistance value became almost equal to the mid value between the value of LRS and the value of HRS. As for the capacitance, the equation: C_{high}=C_{low}/1.5=Cₒₓ/1.5 was established. In view of this, it was confirmed that the threshold value of the transistor was shifted.

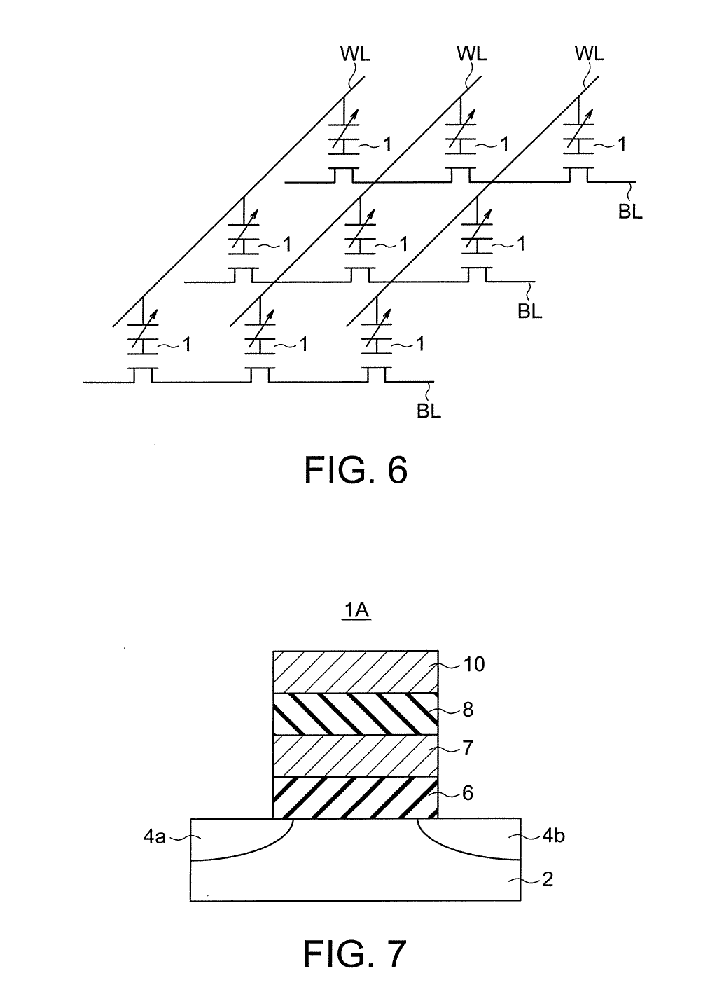

A NAND memory array shown in FIG. 6 was then formed with memory cells 1 of this example. In this memory array, memory cells 1 are arranged in a matrix form, and the electrodes 10 of the memory cells 1 in each column are connected to one word line WL. The memory cells 1 in each row are connected in series, so that the source regions or the drain regions of adjacent memory cells 1 are electrically connected. And the memory cells 1 in each row is connected to a common bit line BL. Performing memory reading based on a change in threshold value, this memory array is the same as a NAND flash memory. The resistance variable layer 8 is of a nonpolar type. For example, a write voltage of 6.0 V was applied, an erase voltage of 8.0 V was applied, and a read voltage of 2.0 V was applied. As a result, it was confirmed that the transistor was turned off in HRS, and was turned on in LRS.

### Example 2

A memory cell in Example 2 is a memory cell 1 having the gate structure of the first embodiment shown in FIG. 1. The memory cell 1 has a bipolar-type material used as the resistance variable layer 8. The memory cell 1 of this example includes: an n-type source region 4a and drain region 4b that are formed in a silicon substrate 2; a tunnel insulating layer 6 that has a layer thickness of 10 nm and is made of LaAlO_{y} (y≈3.0); a resistance variable layer 8 that is doped with Cr, has a layer thickness of 20 nm, and is made of SrZrOₓ (x=1.0 to 3.0); and an electrode 10 that has a film thickness of 20 nm and is made of Ti. The relative permittivity of the tunnel insulating layer 6 made of LaAlO_{y} is 23, and the relative permittivity of the resistance variable layer 8 made of SrZrOₓ is 30. The capacitance C_{high} in HRS is expressed as:

$$\begin{matrix}{C}_{high} = {C}_{ox} {\{ 1 + \frac{{ɛ}_{ox} {d}_{R}}{{ɛ}_{R} {d}_{ox}} \}}^{- 1} \\ = {C}_{ox} {\{ 1 + \frac{23 \times 20}{30 \times 10} \}}^{- 1} \\ = \frac{{C}_{ox}}{2.5}\end{matrix}$$

and the capacitance C_{low} in LRS is expressed as:

C_{low}=Cₒₓ

where Cₒₓ represents the capacitance of the tunnel insulating layer 6 made of LaAlO_{y}, εₒₓ represents the relative permittivity of the tunnel insulating layer 6 made of LaAlO₃, dₒₓ represents the layer thickness of the tunnel insulating layer 6 made of LaAlO₃, ε_{R} represents the relative permittivity of the resistance variable layer 8 made of Cr-doped SrZrOₓ, and d_{R} represents the layer thickness of the resistance variable layer 8 made of Cr-doped SrZrOₓ.

As can be seen from the above equations, when a read voltage was applied, the amount of charges stored in the gate structure of the memory cell 1 in LRS was approximately 2.5 times as large as the amount of charges in HRS. To store the same amount of charges in both cases of LRS and HRS, a voltage approximately 2.5 times as high as the voltage applied in LRS is required in HRS. As a result, it became apparent that the range of the voltage between LRS and HRS, or the range of the threshold voltage of the memory cell, could be made wider by using a high-dielectric film for the tunnel insulating layer 6, and accordingly, a multi-level memory could be more easily produced.

A NAND memory array shown in FIG. 6 was then formed with memory cells of this example. This memory array is the same as the memory array described in Example 1. Whether the transistor is on or off is determined by a shift of the threshold value in this memory array. Therefore, this memory array is the same as a NAND flash memory. Since the resistance variable layer 8 is of a bipolar type in this example, a negative voltage is used for erasing. For example, a write voltage of 6 V was applied, an erase voltage of −6 V was applied, and a read voltage of 2 V was applied. As a result, it was confirmed that the transistor was turned off in HRS, and was turned on in LRS.

### Example 3

A memory cell in Example 3 is a memory cell 1A having the gate structure of the second embodiment shown in FIG. 7. This memory cell 1A has a bipolar-type material used as the resistance variable layer 8. The memory cell 1A of this example includes: an n-type source region 4a and drain region 4b that are formed in a silicon substrate 2; a tunnel insulating layer 6 that has a layer thickness of 4 nm and is made of SiO₂; a lower electrode 7 that has a film thickness of 20 nm and is made of Ag; a resistance variable layer 8 that is doped with Al, has a layer thickness of 20 nm, and is made of ZnO; and an upper electrode 10 that has a film thickness of 20 nm and is made of Ag. The relative permittivity of the tunnel insulating layer 6 made of SiO₂ is 3.8, and the relative permittivity of the resistance variable layer 8 made of ZnO is 8.0. The capacitance C_{high} in HRS is expressed as:

$$\begin{matrix}{C}_{high} = {C}_{ox} {\{ 1 + \frac{{ɛ}_{ox} {d}_{R}}{{ɛ}_{R} {d}_{ox}} \}}^{- 1} \\ = {C}_{ox} {\{ 1 + \frac{3.9 \times 20}{8 \times 4} \}}^{- 1} \\ = \frac{{C}_{ox}}{3.4}\end{matrix}$$

and the capacitance C_{low} in LRS is substantially equal to Cₒₓ, where Cₒₓ represents the capacitance of the tunnel insulating layer 6 made of SiO_{2,} εₒₓ represents the relative permittivity of the tunnel insulating layer 6 made of SiO₂, dₒₓ represents the layer thickness of the tunnel insulating layer 6 made of SiO₂, ε_{R} represents the relative permittivity of the resistance variable layer 8 made of Al-doped ZnO, and d_{R} represents the layer thickness of the resistance variable layer 8 made of Al-doped ZnO.

As can be seen from the above equations, when a read voltage was applied, the amount of charges stored in the gate structure in LRS was approximately 3.4 times as large as the amount of charges in HRS. Accordingly, to store the same amount of charges in both cases of LRS and HRS, a voltage approximately 3.4 times as high as the voltage applied in LRS is required in HRS. As a result, it became apparent that the range of the voltage between LRS and HRS, or the range of the threshold voltage of the transistor, could be made wider by using a low-dielectric material for the resistance variable layer 8, and accordingly, a multi-level memory could be more easily produced.

A NAND memory array shown in FIG. 6 was then formed with memory cells 1A of this example. This memory array is the same as the memory array described in Example 1, except that the memory cells 1 are replaced with the memory cells 1A. Performing memory reading based on a shift in threshold value, this memory array is the same as a NAND flash memory. Since the resistance variable layer 8 was of a bipolar type, a write voltage of 6 V was applied, an erase voltage of −6 V was applied, and a read voltage of 2 V was applied. As a result, it was confirmed that the transistor was turned off in HRS, and was turned on in LRS.

### Example 4

A memory cell in Example 4 is a memory cell 1A having the gate structure of the second embodiment shown in FIG. 7. This memory cell 1A has a nonpolar-type material used as the resistance variable layer 8. The memory cell 1A of this example includes: an n-type source region 4a and drain region 4b that are formed in a silicon substrate 2; a tunnel insulating layer 6 that has a layer thickness of 4 nm and is made of SiO₂; a lower electrode 7 that has a film thickness of 20 nm and is made of TaN; a resistance variable layer 8 that has a layer thickness of 20 nm and is made of NiOₓ (0.5<x<1); and an upper electrode 10 that has a film thickness of 20 nm and is made of Pt. The lower electrode 7 made of TaN serves as a barrier film for restraining diffusion of Ni into the tunnel insulating film 6. The relative permittivity of the tunnel insulating layer 6 made of SiO₂ is 3.8, and the relative permittivity of the resistance variable layer 8 made of NiOₓ is 12.0. The capacitance C_{high} in HRS is expressed as:

$$\begin{matrix}{C}_{high} = {C}_{ox} {\{ 1 + \frac{{ɛ}_{ox} {d}_{R}}{{ɛ}_{R} {d}_{ox}} \}}^{- 1} \\ = {C}_{ox} {\{ 1 + \frac{3.9 \times 20}{12 \times 4} \}}^{- 1} \\ = \frac{{C}_{ox}}{2.6}\end{matrix}$$

and the capacitance C_{low} in LRS is substantially equal to Cₒₓ, where Cₒₓ represents the capacitance of the tunnel insulating layer 6 made of SiO₂, εₒₓ represents the relative permittivity of the tunnel insulating layer 6 made of SiO₂, dₒₓ represents the layer thickness of the tunnel insulating layer 6 made of SiO_{2,} ε_{R} represents the relative permittivity of the resistance variable layer 8 made of NiOₓ, and d_{R} represents the layer thickness of the resistance variable layer 8 made of NiOₓ.

As can be seen from the above equations, when a read voltage was applied, the amount of charges stored in the gate structure in LRS was approximately 2.6 times as large as the amount of charges in HRS. Accordingly, it was found that, to store the same amount of charges in both cases of LRS and HRS, a voltage approximately 2.6 times as high as the voltage applied in LRS was required in HRS. As a result, it became apparent that the range of the voltage between LRS and HRS, or the range of the threshold voltage of the transistor, could be made wider by using a low-dielectric material for the resistance valuable layer 8, and accordingly, a multi-level memory could be more easily produced.

In a case where a nonpolar-type resistance variable layer is employed, a local current path, or a so-called filament, is formed in a direction almost perpendicular to the film plane. Concentration of the current flowing from the filament onto a spot on the tunnel insulating layer adversely affects the reliability of the tunnel insulating layer. To prevent this, the lower electrode is provided between the tunnel insulating layer and the resistance variable layer as in this example, so that concentrated current is dispersed in directions parallel to the film plane. Therefore, it is preferable that a lower electrode is employed together with a nonpolar-type resistance variable layer.

A NAND memory array was then formed with memory cells 1A of this example. This memory array is the same as the memory array described in Example 3, except that the memory cells of Example 3 are replaced with the memory cells of this example. Performing memory reading based on a shift in threshold value, this memory array is the same as a NAND flash memory. Since the resistance variable layer 8 was of a nonpolar type, a write voltage of 6 V was applied, an erase voltage of 8 V was applied, and a read voltage of 2 V was applied. As a result, it was confirmed that the transistor was turned off in HRS, and was turned on in LRS.

The above described combination of the tunnel insulating layer 6, the resistance variable layer 8, and the upper electrode 10 of Example 4 is merely an example. For example, the tunnel insulating layer 6 that forms the gate structure may be a silicon oxide or a silicon oxynitride, or an oxide or oxynitride containing at least one element of the group consisting of alkali earth metals, rare earth metals, Ti, Zr, Hf, and Al.

Also, the resistance variable layer 8 that forms the gate structure and is made of a metal oxide is preferably deficient of oxygen in terms of the stoichiometric composition, or is preferably of an oxygen-deficient type. Alternatively, the resistance variable layer 8 is preferably doped with 3 atomic % or less of a metal such as Al, V, Nb, Ta, Cr, Mo, or W.

As can be seen from the equations in Examples 1 to 4, the ratio between the capacitance C_{low} in LRS and the capacitance C_{high} in HRS (=C_{low}/C_{high}) becomes higher, if the value of (εₒₓ/dₒₓ)/(ε_{R}/d_{R}) is large, where εₒₓ represents the relative permittivity of the tunnel insulating layer 6, dₒₓ represents the layer thickness of the tunnel insulating layer 6, ε_{R} represents the relative permittivity of the resistance variable layer 8, and d_{R} represents the layer thickness of the resistance variable layer 8. In other words, the ratio between the voltage in HRS and the voltage in LRS becomes higher when the same amount of charges are stored in both cases of HRS and LRS, and more multiple values can be stored. Accordingly, in a case where the material and the layer thickness of the tunnel insulating layer 6 are not to be changed, the material and the layer thickness of the resistance variable layer 8 should be selected so that the ratio between the relative permittivity ε_{R} and the layer thickness d_{R} of the resistance variable layer 8 (=ε_{R}/d_{R}) becomes small. In a case where the material and the layer thickness of the resistance variable layer 8 are not to be changed, the material and the layer thickness of the tunnel insulating layer 6 should be selected so that the ratio between the relative permittivity εₒₓ and the layer thickness dₒₓ of the tunnel insulating layer 6 (=εₒₓ/dₒₓ) becomes large.

Further, each of the electrodes 7 and 10 may be made of either a semiconductor or a metal.

Also, since each nonvolatile semiconductor memory element of the embodiments of the present invention can be formed in the smallest possible size as a memory element, a memory device having a NAND array including such memory elements is particularly suitable for miniaturization.

It should be noted that the present invention is not limited to the above specific embodiments, and various modifications may be made to them in practice without departing from the scope of the invention.

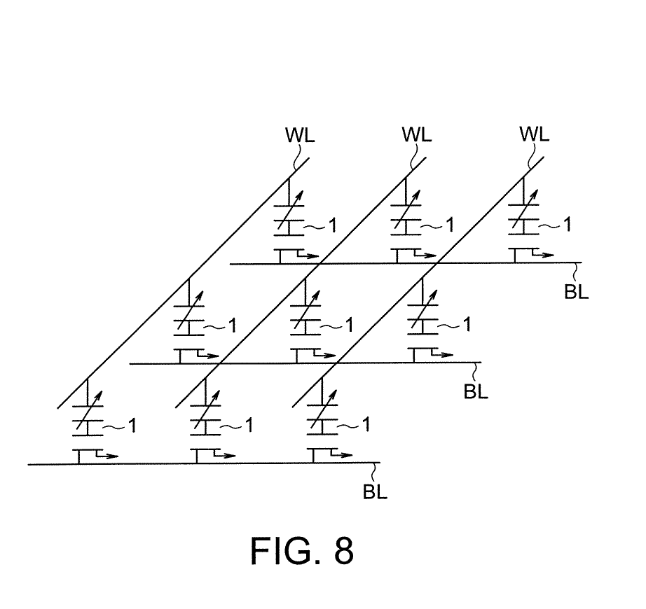

In Examples 1 to 4, each NAND memory array is formed with memory cells of one of the embodiments of the present invention. However, memory cells of each embodiment of the present invention may also form a NOR memory array shown in FIG. 8. In this NOR memory array, memory cells of the first or second embodiments of the present invention are arranged in a matrix form. The electrodes 10 of the memory cells in each column are connected to a common word line WL. As for the memory cells in each row, the drain regions 4b are connected to a common bit line, and the source regions 4a are connected to ground. This NOR memory array can perform writing, erasing, and reading with the same voltage as the voltage applied in a NAND memory array. In the case of the NOR type, the cell area is as large as 6F² at the minimum, but random access is possible.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A nonvolatile semiconductor memory element comprising:
a semiconductor substrate;
a source region and a drain region formed at a distance from each other in the semiconductor substrate; and
a gate structure formed on a portion of the semiconductor substrate, the portion being located between the source region and the drain region, the gate structure including a tunnel insulating layer, a resistance variable layer formed above the tunnel insulating layer and made of a metal oxide, and a first electrode formed on the resistance variable layer.

2. The memory element according to claim 1, wherein the gate structure further includes a second electrode that is formed between the tunnel insulating layer and the resistance variable layer.

3. The memory element according to claim 1, wherein the resistance variable layer has resistance varied by applying a voltage across the first electrode of the gate structure and the semiconductor substrate, so that a threshold value of the transistor is shifted.

4. The memory element according to claim 1, wherein the tunnel insulating layer is a silicon oxide film or a silicon oxynitride film.

5. The memory element according to claim 1, wherein the tunnel insulating layer is formed with an oxide or an oxynitride containing at least one of an alkali earth metal, a rare earth metal, Ti, Zr, Hf, and Al.

6. The memory element according to claim 1, wherein the resistance variable layer is formed with an oxygen-deficient metal oxide.

7. The memory element according to claim 1, wherein the resistance variable layer is formed with a metal oxide doped with 3.0 atomic % or less of Al, V, Nb, Ta, Cr, Mo, or W.

8. A nonvolatile semiconductor memory device comprising
a plurality of nonvolatile semiconductor memory elements according to claim 1, the nonvolatile semiconductor memory elements being arranged in a matrix form, the first electrodes of the nonvolatile semiconductor memory elements in each column being connected to a word line, the nonvolatile semiconductor memory elements in each row being aligned in series.

9. The memory device according to claim 8, wherein the gate structure further includes a second electrode that is formed between the tunnel insulating layer and the resistance variable layer.

10. The memory device according to claim 8, wherein the resistance variable layer has resistance varied by applying a voltage across the first electrode of the gate structure and the semiconductor substrate, so that a threshold value of the transistor is shifted.

11. The memory device according to claim 8, wherein the tunnel insulating layer is a silicon oxide film or a silicon oxynitride film.

12. The memory device according to claim 8, wherein the tunnel insulating layer is formed with an oxide or an oxynitride containing at least one of an alkali earth metal, a rare earth metal, Ti, Zr, Hf, and Al.

13. The memory device according to claim 8, wherein the resistance variable layer is formed with an oxygen-deficient metal oxide.

14. The memory device according to claim 8, wherein the resistance variable layer is formed with a metal oxide doped with 3.0 atomic % or less of Al, V, Nb, Ta, Cr, Mo, or W.

15. A nonvolatile semiconductor memory device comprising
a plurality of nonvolatile semiconductor memory elements according to claim 1, the nonvolatile semiconductor memory elements being arranged in a matrix form, the first electrodes of the nonvolatile semiconductor memory elements in each column being connected to a common word line, the drain regions of the nonvolatile semiconductor memory elements in each row being connected to a common bit line, and the source regions of the nonvolatile semiconductor memory elements in each row being connected to ground.

16. The memory device according to claim 15, wherein the gate structure further includes a second electrode that is formed between the tunnel insulating layer and the resistance variable layer.

17. The memory device according to claim 15, wherein the resistance variable layer has resistance varied by applying a voltage across the first electrode of the gate structure and the semiconductor substrate, so that a threshold value of the transistor is shifted.

18. The memory device according to claim 15, wherein the tunnel insulating layer is a silicon oxide film or a silicon oxynitride film.

19. The memory device according to claim 15, wherein the tunnel insulating layer is formed with an oxide or an oxynitride containing at least one of an alkali earth metal, a rare earth metal, Ti, Zr, Hf, and Al.

20. The memory device according to claim 15, wherein the resistance variable layer is formed with an oxygen-deficient metal oxide.
